(19) United States
(12) Patent Application Publication
(10) Pub. No.: US 2013/0182405 A1
(43) Pub. Date: Jul. 18, 2013

(54) NANOWIRE ENHANCED TRANSPARENT CONDUCTOR AND POLARIZER

(71) Applicant: Lawrence A. Kaufman, Waltham, MA (US)

(72) Inventor: Lawrence A. Kaufman, Waltham, MA (US)

(73) Assignee: Lightwave Power, Inc., Cambridge, MA (US)

(21) Appl. No.: 13/731,115

(22) Filed: Dec. 31, 2012

Related U.S. Application Data
(60) Provisional application No. 61/582,001, filed on Dec. 30, 2011.

(51) Int. Cl. H05K 1/02; F21V 9/14; F21V 13/08; G09F 13/04

(52) U.S. Cl. CPC H05K 1/0274; G09F 13/04; F21V 9/14; F21V 13/08
USPC 362/19; 174/253; 362/97.2

(57) ABSTRACT

An electrically conducting wire pattern constructed from nanometer or micrometer dimension wires. The electrically conducting wire pattern can be designed with various geometries, including rectangular, triangular and circular arrays, and combinations of such patterns. The electrically conducting wire pattern can provide improved optically transmissive electrical conductors and can provide improved polarizers for use with various electrical and optical devices and components.

### CROSS-REFERENCE TO RELATED APPLICATIONS

This application claims priority to and the benefit of co-pending U.S. provisional patent application Ser. No. 61/582,001, filed Dec. 30, 2011, which application is incorporated herein by reference in its entirety.

### FIELD OF THE INVENTION

The invention relates to transparent media in general and particularly to media that are transparent to optical wavelengths.

### BACKGROUND OF THE INVENTION

Transparent conductors today are usually made from semiconductors, the bandwidths of which are chosen so that thermally activated charge carriers are produced at room temperatures, but light absorption at certain wavelengths is minimized Examples of these transparent semiconductors include ITO (indium-tin-oxide) and zinc oxide. The thickness of transparent semiconductors is usually chosen to provide adequate in-plane electrical conductivity for a chosen product, but results in an expensive and brittle material with relatively low optical transmission. Organic conductors such as PEDOT:PSS do not have adequate electrical conductivity in reasonable thicknesses to satisfy most product requirements. Transparent conductors based on carbon nanotubes (CNTs) do not exhibit the combination of high optical transmission and high surface conductivity required for many applications.

Semiconductor-based transparent conductor properties are always constrained by a compromise between light absorption and electrical conductivity, since both properties are determined by the semiconductor bandwidth. Larger bandwidths reduce light absorption over some wavelengths and decrease electrical conductivity, while smaller bandwidths increase light absorption over some wavelengths and increase electrical conductivity.

There is a need for improved conductors that provide both adequate optical transparency and adequate electrical conductivity.

### SUMMARY OF THE INVENTION

According to one aspect, the invention features an optically transmissive electrical conductor. The optically transmissive electrical conductor comprises a substrate having at least one surface; and an electrically conducting wire pattern disposed on the surface of the substrate, the electrically conducting wire pattern having wire dimensions smaller than a first wavelength of incident electromagnetic radiation, the optically transmissive electrical conductor configured to respond to the incident electromagnetic radiation having the first wavelength by transmitting the first wavelength through the conductor.

In one embodiment, the electrically conducting wire pattern comprises a wire geometry selected to minimize a number of plasmon or polariton modes supported by the electrically conducting wire pattern.

In another embodiment, the wire geometry is selected from a geometry consisting of a rectangle, a triangle, a circular geometry, and combinations thereof

In yet another embodiment, the optically transmissive electrical conductor further comprises a continuous optically transmissive electrical conductor disposed adjacent the electrically conducting wire pattern.

In still another embodiment, the electrically conducting wire pattern comprises a metal selected from the group consisting of gold, silver, molybdenum, and aluminum.

In a further embodiment, the electrically conducting wire pattern comprises a semiconductor material selected from the group consisting of indium-tin-oxide and zinc oxide.

In yet a further embodiment, the optically transmissive electrical conductor further comprises an insulation layer situated between the surface of the substrate and the electrically conducting wire pattern.

In an additional embodiment, the optically transmissive electrical conductor is provided as a component in a device that is viewed by a viewer.

In one embodiment, the optically transmissive electrical conductor is provided in combination with at least one of a backlight; and a liquid crystal display

In another embodiment, the optically transmissive electrical conductor and the backlight in combination are configured to produce a polarized light having an intensity greater than 50% of the intensity of the backlight without the optically transmissive electrical conductor.

In yet another embodiment, the optically transmissive electrical conductor and the liquid crystal display in combination are configured to produce a display adapted to present information to a user.

In one embodiment, the optically transmissive electrical conductor is present in combination with a separate light source situated on a first side of the optically transmissive electrical conductor, wherein the optically transmissive electrical conductor is configured as a first wire grid polarizer to transmit one polarization of the incident electromagnetic radiation emitted by the light source beyond the optically transmissive electrical conductor, and to reflect an orthogonal polarization of the incident electromagnetic radiation back toward the light source on the first side of the optically transmissive electrical conductor.

In another embodiment, the optically transmissive electrical conductor further comprises a liquid crystal display situated on a second side of the optically transmissive electrical conductor, and further comprising a second wire grid polarizer configured as an analyzer, the second wire grid polarizer configured to reflect light orthogonal to its pass axis at a surface of the liquid crystal display distal to the first wire grid polarizer, so that such reflected light is propagated back through the liquid crystal display and toward the light source.

In yet another embodiment, the optically transmissive electrical conductor further comprises a liquid crystal display situated on a second side of the optically transmissive electrical conductor; a reflector; and a quarter wave plate; the light source, the reflector, the wave plate and the optically transmissive electrical conductor configured as the first wire grid polarizer are mutually arranged to transmit one polarization of the electromagnetic radiation emitted from the light source through the first wire grid polarizer to the liquid crystal display, and to reflect an orthogonal polarization of the electromagnetic radiation emitted from the light source from the first wire grid polarizer to the quarter wave plate, wherein the quarter wave plate is configured to rotate a plane of polarization of the orthogonal polarization so that upon reflection by the reflector, a resultant illumination is transmitted through the first wire grid polarizer.

According to another aspect, the invention relates to a method of generating polarized light. The method comprises the steps of providing a source of unpolarized light having a wavelength λ, the source of unpolarized light producing light having an intensity I₀ per unit area; causing the unpolarized light having the intensity I₀ per unit area to impinge on an electrically conducting wire pattern disposed on a surface of a material transparent at the wavelength λ; causing light reflected backward from the electrically conducting wire pattern to impinge on a surface that randomizes by reflection a plane of polarization of the backwardly reflected light; and causing the light having the randomized plane of polarization to again impinge on the electrically conducting wire pattern disposed on the surface of the material transparent at the wavelength λ; whereby a fraction F of the unpolarized light having a wavelength λ and an intensity I₀ per unit area is transmitted through the surface of the electromagnetically transparent material in a selected polarization, where F is more than 50%.

In another embodiment, the transmitted light is in a first polarization state and the reflected light is in a second polarization state orthogonal to the first polarization state.

In yet another embodiment, the transmitted light is used to operate a liquid crystal display.

The foregoing and other objects, aspects, features, and advantages of the invention will become more apparent from the following description and from the claims.

### BRIEF DESCRIPTION OF THE DRAWINGS

The objects and features of the invention can be better understood with reference to the drawings described below, and the claims. The drawings are not necessarily to scale, emphasis instead generally being placed upon illustrating the principles of the invention. In the drawings, like numerals are used to indicate like parts throughout the various views.

FIG. 1 is a diagram that illustrates a typical wire mesh structure 102 in the classical optical regime. In this regime the dimensions shown are ˜4 microns <W<˜30 microns and ˜20 microns <L<˜150 microns.

FIG. 2 is a diagram that illustrates a typical wire mesh structure 205 in the light scattering regime. In this regime the dimensions shown are ˜0.5 microns <W<˜3 microns and ˜2.5 microns <L<˜15 microns.

FIG. 3 is a diagram that illustrates a typical wire mesh structure 302 in the plasmon interaction regime. In this regime the dimensions shown are ˜20 nanometers <W<˜300 nanometers and ˜100 nanometers <L<˜1500 nanometers.

FIG. 4 is a diagram that illustrates a typical wire mesh structure in either classical optical, light scattering or plasmon interaction regime with appropriate wire mesh structure dimensions as specified with regard to FIG. 1, FIG. 2, and FIG. 3. In this figure, the background 402 represents a field conductor, an optically transmissive electrical conductor that fills the spaces outside the wire mesh structures and provides continuity of electrical conduction in the meta-conductor.

FIG. 5A is a diagram that illustrates a square array wire mesh geometry.

FIG. 5B is a diagram that illustrates a triangular array wire mesh geometry.

FIG. 5C is a diagram that illustrates a circular array wire mesh geometry.

FIG. 5D is a diagram that illustrates an array that employs a combination of geometries.

FIG. 6A is a diagram that illustrates a square array wire mesh geometry with various wire widths.

FIG. 6B is a diagram that illustrates a triangular array wire mesh geometry with various wire widths.

FIG. 6C is a diagram that illustrates a circular array wire mesh geometry with various wire widths.

FIG. 6D is a diagram that illustrates an array that employs a combination of geometries with various wire widths.

FIG. 7A is a schematic diagram illustrating a first wire mesh geometry that provides both conductivity and transmission with polarization effect.

FIG. 7B is a schematic diagram illustrating a second wire mesh geometry that provides both conductivity and transmission with polarization effect.

FIG. 8 is a graph that shows the results of modeling light transmission of 50, 100 and 200 nanometer wide silver wires with height of 100 nanometers in a square pattern with dimensions of 1 micron on a side. Curve 801 is the result for 50 nanometer wires, curve 802 is the result for 100 nanometer wires and curve 803 is the result for 200 nanometer wires.

FIG. 9 is a perspective schematic diagram of a wire mesh structure such as that of any of FIG. 1, FIG. 2, FIG. 3 and FIG. 4 on a substrate 910, which substrate can be transparent to electromagnetic radiation having a wavelength of interest.

FIG. 10 illustrates a prior art LCD design,

FIG. 11 illustrates a cross section of an embodiment of the invention, which is based on a wire grid polarizer (WGP).

FIG. 12 illustrates a liquid crystal display with a WGP.

FIG. 13 illustrates an embodiment in which an ITO transparent conductor is replaced by the wire grid polarizer.

FIG. 14 illustrates a design in which a WGP analyzer may be placed within a LCD.

### DETAILED DESCRIPTION

This invention pertains to the field of transparency of a medium to optical and other electromagnetic wavelengths, electrical conductivity of that same medium, and applications of novel structures based on electrically conducting wires with dimensions so small that light absorption in the wires is minimized through control of light scattering and plasmon modes in the wires.

As used herein, the term “optically transmissive electrical conductor” is used to describe a structure that has the following properties. With regard to unpolarized light, if the optically transmissive electrical conductor is not configured to perform as a polarizer, any light that impinges on the optically transmissive electrical conductor passes through with minimal reflection or absorption. The optically transmissive electrical conductor is set up as a polarizer, only the light that is polarized so as to pass through a polarizer is transmitted and the remaining light which is not properly oriented in polarization is reflected. Thus, a completely polarized incident illumination having the correct polarization orientation will pass through the optically transmissive electrical conductor with minimal reflection of absorption.

In particular, reference is made to materials commonly known as transparent conductors and optical polarizers, with new conductivity, transparency, and light absorption improvements due to the introduction of micron-size and nano-size continuous wire mesh structures. The wire mesh structures can be designed to have minimum absorbance of certain frequencies of light or electromagnetic wavelengths so as to permit a maximum transmission or reflection of desired wavelengths of radiation, and simultaneously to lower the in-plane electrical resistance of optically transmissive electrical conductors. Polarizing structures can also be designed to minimize parasitic light absorption. As used herein the term “transparency” is intended to refer to transparency to radiation comprising electromagnetic radiation including light wavelengths in the visible part of the electromagnetic spectrum. As used herein the term “nanowires” is intended to refer to wires made of metals or suitable semiconductors or other electrically conducting materials, with dimensions smaller or much smaller than relevant wavelengths of light, such that light absorption in the nanowires is minimized.

We describe new types of transparent conducting materials and polarizers and methods of creating new types of transparent conducting materials and polarizers. A feature of the invention is the use of micron-size and nano-size wire mesh structures, either alone or in combination with transparent conducting materials or transparent field conductors in which the wire mesh structures are embedded. The introduction of wire mesh structures into a matrix that can include transparent, but sometimes thinner than currently used field conductors, provides a partial decoupling of the radiation transparency and the in-plane electrical conductivity. Current transparent materials made of semiconductors have their electrical conductivity and radiation (light) transmission properties coupled through the band-gap of the semiconductors. In the structures and embodiments disclosed here, the electrical conductivity is partially determined by the wire mesh structures and partially by the field conductors. The wire meshes produce electrical conductivities that can be higher than that of the field conductor alone. We shall refer to structures containing a continuous wire mesh and an optically transmissive electrical conductor as “meta-conductors”, which are different than field conductors with discontinuous wires randomly distributed in the field conductors and different from transparent conductors without embedded wire mesh structures.

When the elements of the wire mesh structures have width and height dimensions larger than or much larger than the wavelength of incident light, the wire mesh structures interact with light in a classical mode where the light radiation primarily is reflected from the wire mesh structures. When the elements of the wire mesh structures have width and height dimensions on the order of wavelengths of light, the wire mesh structures interact with light in a light-scattering mode that reduces bulk light absorption and reflection compared to that from elements operating in the classical mode. When the elements of the wire mesh structures have width and height dimensions below and much below the wavelengths of incident radiation, which we call nanowires, light absorption in elements of suitable classes of materials such as metals including but not limited to silver, gold and aluminum, is primarily determined by light-induced plasmons and polaritons, hereafter referred to as plasmons, and plasmon modes in the wire mesh elements induced by the incident light. Plasmons and polaritons are collective electron excitations, the electromagnetic fields of which are mostly outside the wire mesh structures, thus minimizing absorption of the electromagnetic energy within the nanowires. The geometry of the nanowires and wire mesh structures can be chosen to minimize the number of plasmon modes excitable at certain chosen electromagnetic frequencies, and thus the absorption of light at these chosen frequencies, which is a function of the number and types of excited Plasmon modes in the wires, can be minimized

The plasmon response can be modified and minimized by choosing the shape of the wire mesh elements, their geometric layout, their sizes and the materials that make up the elements of the wire mesh structure. The in-plane conductivity is primarily determined by the width, thickness and height of the wire mesh elements, the in-plane density of these elements and the design of the wire mesh array that the elements form. Polarizers made up of nanowires alone are predicted to show minimum light absorption and thus, the efficiency of the polarizer which is the percent of light polarized, should be much higher than the efficiency of conventional polarizers.

The field conductor is a transparent conductor, the purpose of which is to provide electrical conductivity in the areas outside of the wire mesh structures. The field conductor can be a transparent semiconductor, much thinner than stand-alone transparent semiconductors such as indium-tin-oxide or an organic material such as PEDOT:PSS. The resultant field conductors minimize optical transmission losses while providing continuity of electrical conductivity in the spaces not covered directly by the wire mesh structures. In some cases and for some applications, the field conductor is not needed and can be absent from the optically transmissive electrical conductor.

The optically transmissive electrical conductors use micron-size and nano-size wire mesh structures, either alone or in combination with other transparent conducting materials to create electrically conductive materials with optical transmission values for certain wavelengths of radiation that can be greater than for grids operating in the classical optical regime (which is described below). The effect of adding a wire mesh structure is to break the correlation between light transparency and electrical conductivity in semiconductors. For example, the overall light transmission and electrical conductivity of a meta-conductor is determined by the separate properties of the field conductor and the wire mesh structure.

The prior art, which is listed in the References, has described improved transparent conductors with wire mesh structures added to semi-transparent conductors, but with wire mesh dimensions on the order of a few microns to hundreds of microns. This is the classical optical regime as described below.

Incident light that falls on a surface can be accounted for according to the following equation, in which I_{incident} is the intensity of incident light, I_{transmitted} is the intensity of transmitted light, I_{reflected} is the intensity of reflected light, and I_{absorbed} is the intensity of absorbed light:

I_{incident}=I_{transmitted}+I_{reflected}+I_{absorbed} Eqn. (1)

If the intensity of the transmitted light and the intensity of the reflected light are maximized, the intensity of the absorbed light will be minimized

There are three different regimes that describe light interactions with the wire mesh structures.

### THE CLASSICAL REGIME

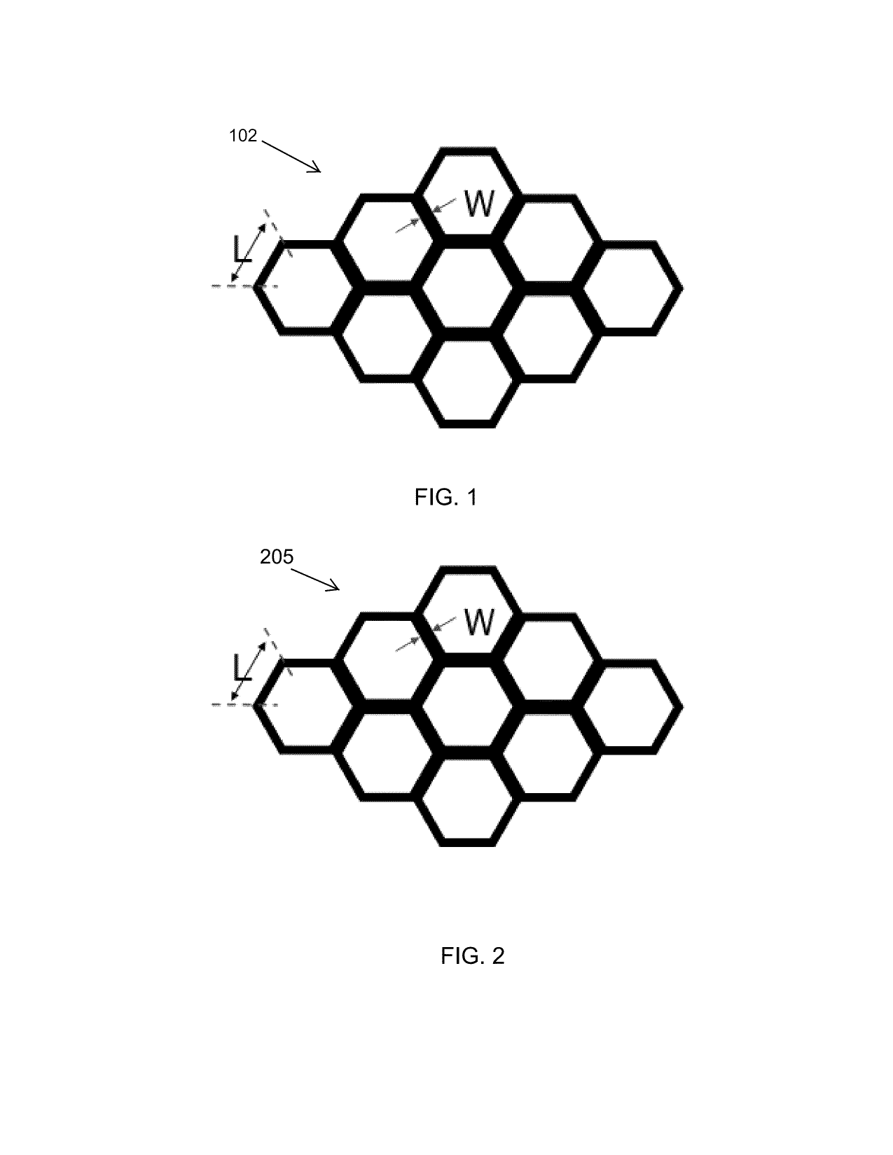

The classical optical regime involves light wavelengths that are much smaller than the wire mesh structure dimensions, which can be the dimensions of either the wires themselves that make up the wire mesh, or the dimensions of the wire mesh unit cells formed by the wires. Light interaction with the wire mesh structures is determined by reflection, absorption, and transmission of light by the wire mesh structure. These interactions are described in the literature as determined by ray optics, and the bulk optical properties of the wires making up the wire meshes, and independently by the additional absorption/reflection of the transparent semiconductor. A typical wire mesh structure is shown in FIG. 1 without the addition of a transparent field conductor and in FIG. 4 with the addition of a transparent field conductor.

### THE LIGHT SCATTERING REGIME

The light scattering regime involves a wavelength of light that is approximately the same size as the dimensions of the wire mesh structures. In this regime light absorption by the wire mesh structures is determined by scattering of light and by diffraction effects and is relatively independent of the bulk optical properties of the wires making up the wire meshes. A typical wire mesh structure is shown in FIG. 2 without the addition of a transparent field conductor and in FIG. 4 with the addition of a transparent field conductor.

### THE PLASMON INTERACTION REGIME

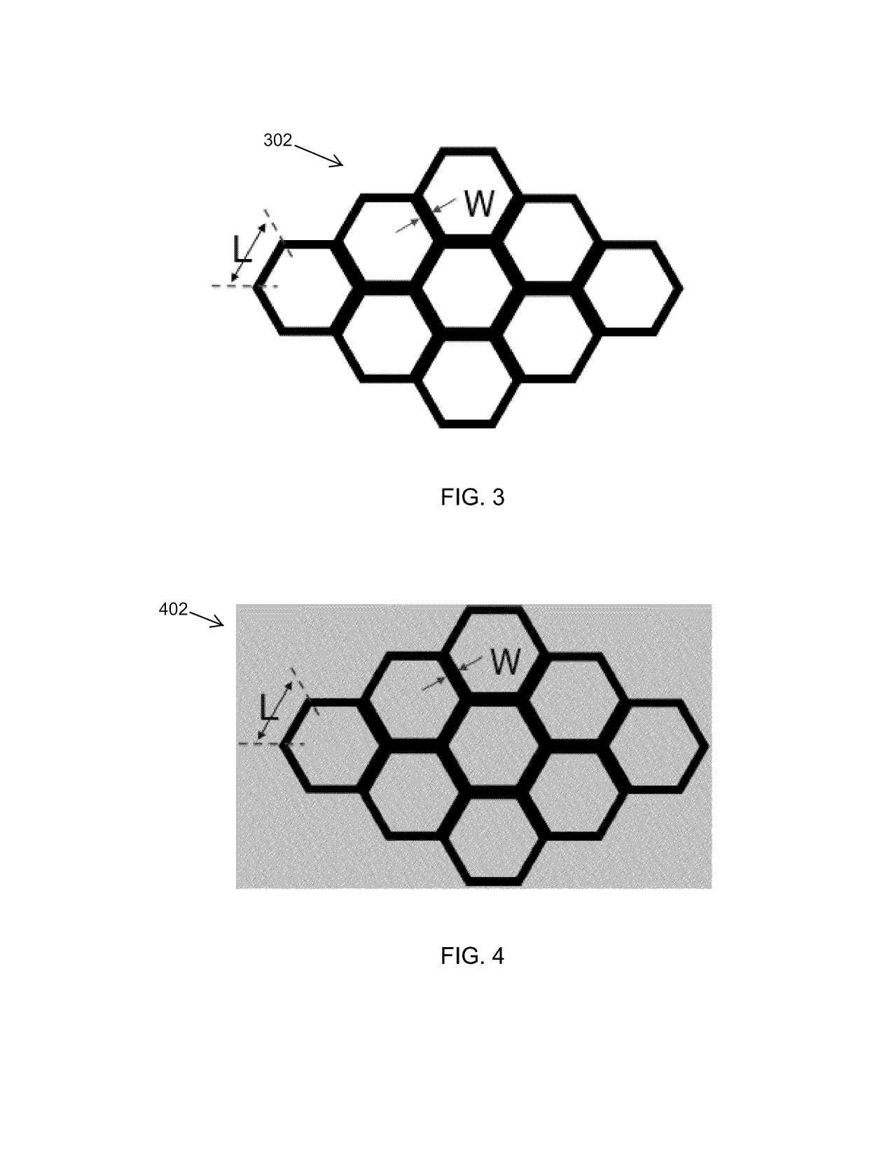

The plasmon interaction regime involves a wavelength of light is much larger than the dimensions of the wire mesh structures. In some embodiments, these wire structures have dimensions of the order of hundreds of nanometers. In this regime light absorption by the wire mesh structures is determined by resonances with certain frequencies of electromagnetic radiation including light that excites plasmon modes in the wires. If the geometry and materials of the wire mesh structures are chosen appropriately, the plasmon modes can be minimized and can be reduced to zero or near to zero at certain wavelengths of light. Thus light absorption by the wire mesh structures can be further reduced compared to light absorption in the classical optical regime or the scattering light regime. A typical wire mesh structure is shown in FIG. 3 without the addition of a transparent field conductor and in FIG. 4 with the addition of a transparent field conductor.

The objectives of the current disclosure are therefore (1) to provide a transparent conductive material comprising a metallic geometric grid structure with wire dimensions approximately equal to the wavelengths of incident light, or smaller or much smaller than the wavelengths of incident light in order to achieve a greater optical transmission than can be achieved in the above-defined classical regime and (2) to provide a polarizer made up of nanowires such that parasitic light absorption is minimized and the polarization efficiency, the ratio of polarized to unpolarized light from the device, is increased.

### DESIGN OF THE OPTICALLY TRANSMISSIVE ELECTRICAL CONDUCTOR

It is known that extreme transmission (i.e., the degree of transmission exceeds that predicted by classical transmission theory) can be observed in a thin metallic film through perforations in the film that are of sub-wavelength size. Such extreme transmission is predominately explained as resulting from the excitation of surface plasmons, collective electrons existing in metals, when the resonant conditions between the electromagnetic waves and surface plasmons are satisfied. Additional mechanisms such as grating and photonic interactions between photons and the metallic structures also contribute to the extreme degree of transmission. It has been demonstrated that the degree of transmission and regions of wavelengths that can achieve such transmission can be controlled by varying the geometry, periodicity, size, and the surrounding environment of the perforations, and the material choice of the metal film.

Similar mechanisms, including the combination of plasmonic, grating and photonic effects, dominate the degree of transmission in the disclosed wire mesh optically transmissive electrical conductor. The parameters that have been used to manipulate transmission of perforated films can also be used to control the transmission of disclosed wire mesh optically transmissive electrical conductor. These parameters include, but not limited to, the geometry, periodicity, size, the dielectric value of the surrounding environment, and the material choice of the wires.

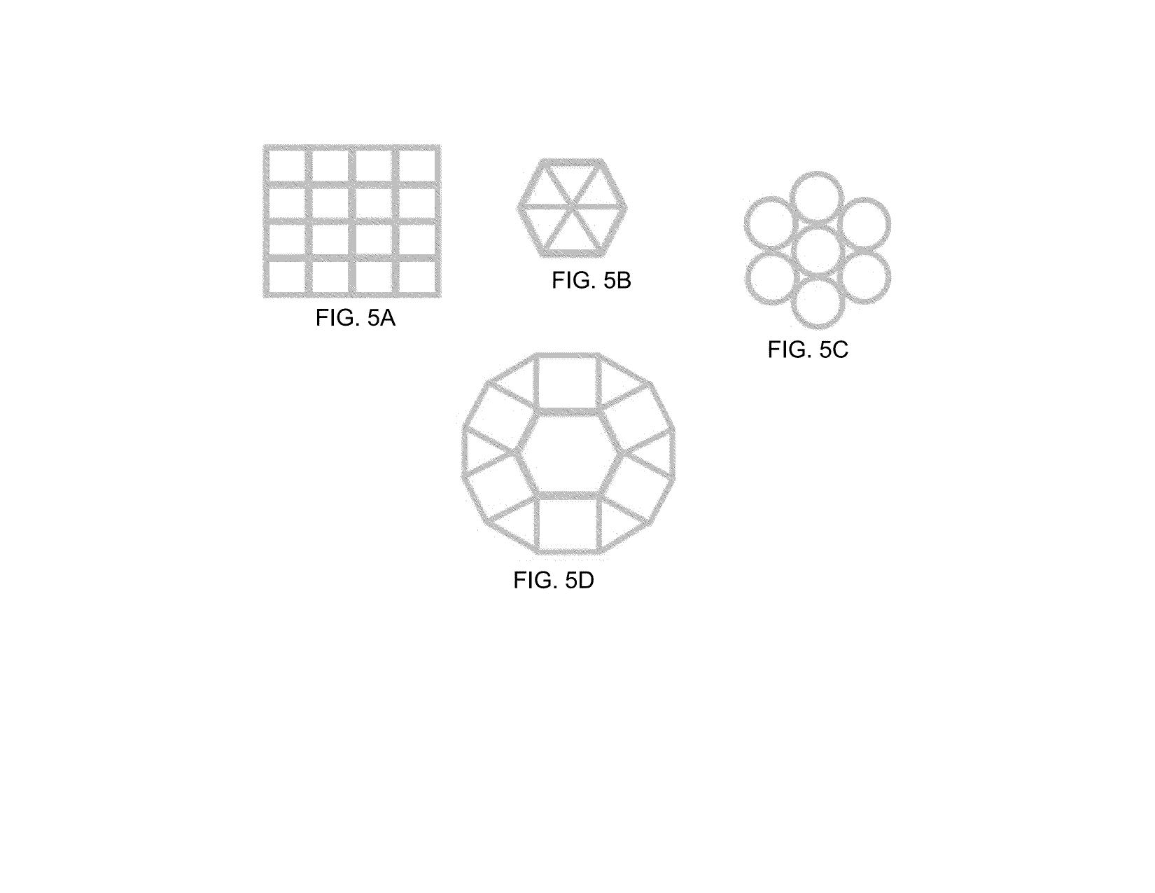

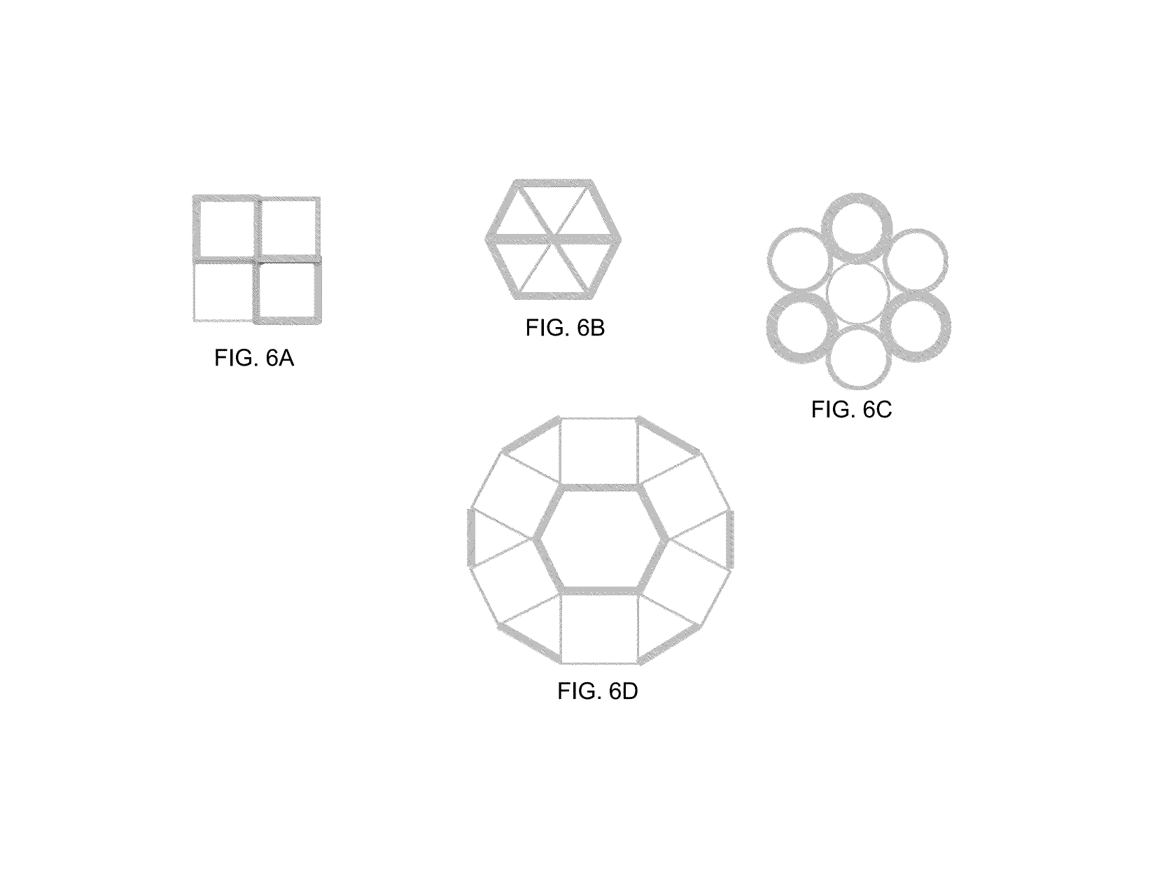

The wire mesh can take the form of various geometries as shown in FIG. 5A through FIG. 5D. The geometries of wire mesh can be hexagonal as disclosed in FIG. 1-4, or other geometries such as, but not limited to, square array (FIG. 5A), triangle array (FIG. 5B), circle array (FIG. 5C), and combination of different geometries such as (FIG. 5D). The wire mesh can also take form of arrays of wires with various widths as shown in FIG. 6A through FIG. 6D.

Simulation techniques such as finite-difference time-domain (FDTD) and rigorous-coupled wave analysis (RCWA) algorithms have been developed to guide the design of the aforementioned perforated structures for maximum transmission or transmission in a controlled manner. Similar techniques can be used to optimize the disclosed wire mesh structure to guide towards an effective structure that offers desirable transmission.

The conductivity of the wire mesh can be simulated and designed with techniques such as a rigorous circuit simulation package (SPICE), which is commonly used to model resistivity and conductivity of wire networks.

### ADDITIONAL FUNCTIONALITIES OF DISCLOSED OPTICALLY TRANSMISSIVE ELECTRICAL CONDUCTOR

The geometry of the wire mesh structures in the disclosed optically transmissive electrical conductor can be designed to have maximum transmission of electromagnetic waves of certain regions of the electromagnetic spectrum, but minimum transmission in other regions, while maintaining good conductivity throughout the whole wavelength spectrum. In other words, the conductive wire mesh can be transparent to certain regions of electromagnetic waves, but has shielding effect in other wavelength regions. For example, when the openings of the wire mesh (i.e., the areas between neighboring wires) are of nanometer or micron scale, the wire mesh is essentially transparent to electromagnetic waves of up to approximately 20 μm, but has shielding effect to electromagnetic waves that have wavelength larger than 20 μm.

According to similar design principles, such wire mesh can be designed as conductive, optically transparent but heat insulating or radio frequency shielding. Such wire mesh may have applications in the EMI shielding industry, as well as in the military sector.

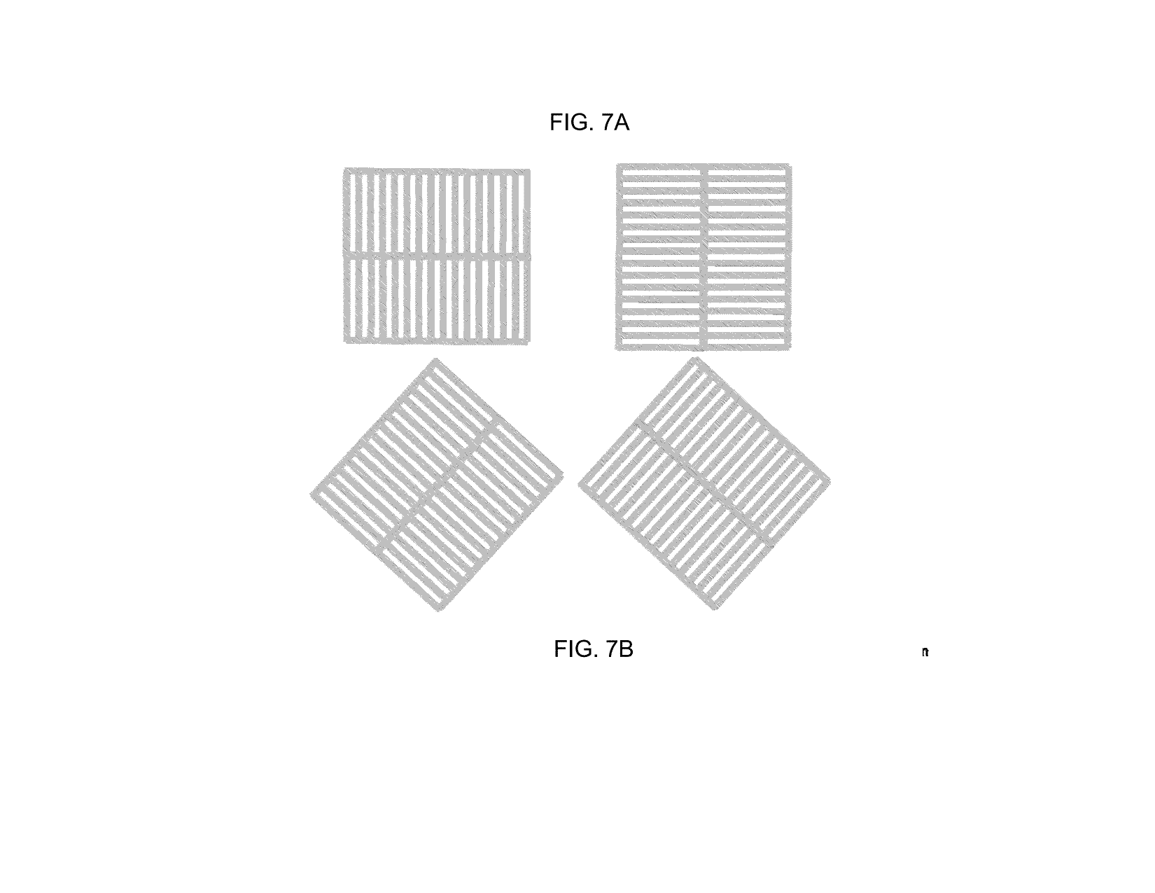

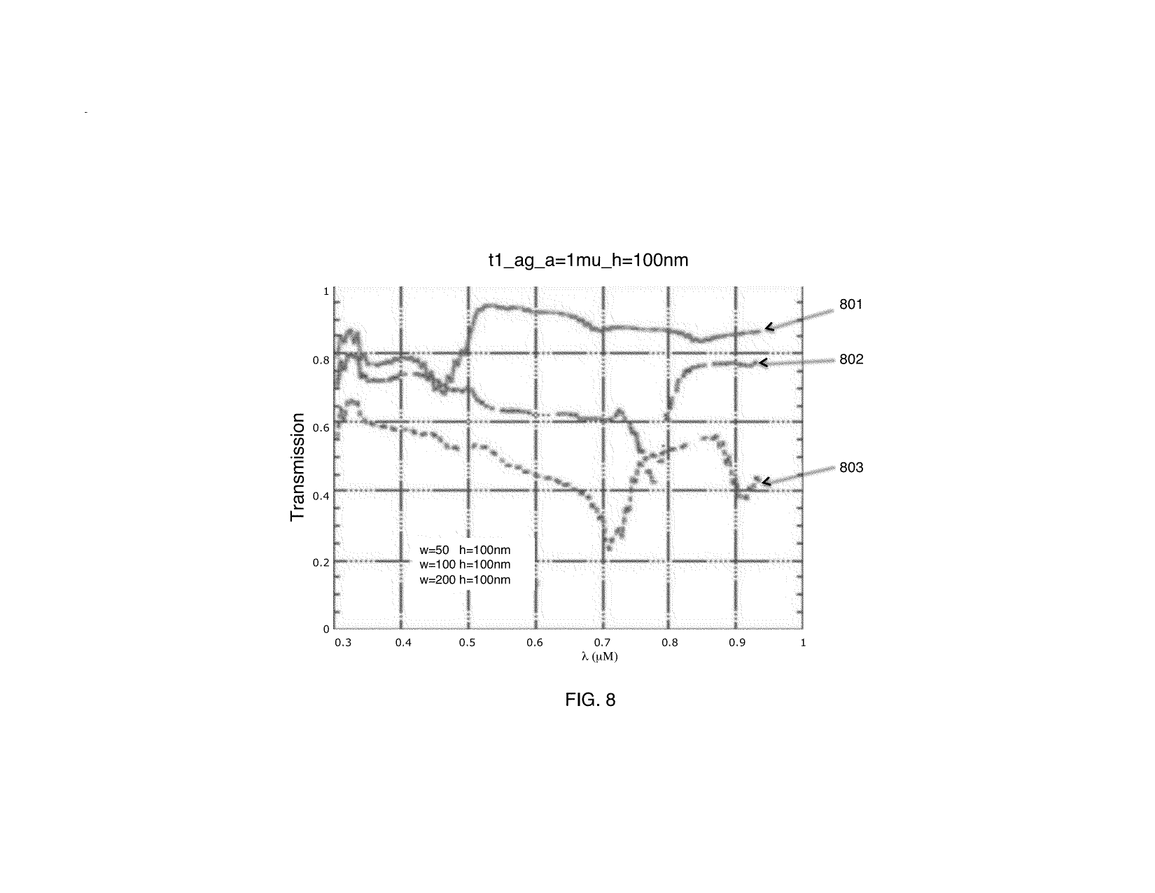

The geometry of the mesh can also be designed to function as a polarizer while a conductor. FIG. 7A and FIG. 7B show examples of such design. FIG. 7A shows two polarizers in crossed or orthogonal configuration. FIG. 7B shows two other polarizers in crossed or orthogonal configuration. This type of design incorporating nanowire structures will minimize light absorption and thus maximize light polarization and polarization efficiency.

### DESIGN OF THE NANOWIRE POLARIZER

The design of a nanowire polarizer is similar to the design of conventional wire polarizer, which usually comprises many parallel electrically conducting wires supported on an optically or electromagnetically transparent frame. The wire spacing and wire dimensions are a function of the wavelengths of incoming light (and electromagnetic radiation) that are desired to be polarized.

The difference is that in a nanowire polarizer, the dimensions of the wires are chosen to minimize the number of plasmon modes that the wire will support and to choose wire structures that only interact with the incoming electromagnetic radiation through plasmonic interactions. In this way, the electromagnetic field of the incoming radiation produces collective excited electron modes in the wires such that most of the excited electron electromagnetic radiation is outside the wires and does not contribute to the parasitic absorption of the incoming radiation energy. The plasmon, or excited electron modes, then collapse and outgoing radiation is emitted.

Thus, incoming radiation interacts with the wires through the creation of collective electron excitations which then collapse and produce outgoing radiation that is either transmitted or reflected and either polarized or not polarized, with minimum absorption of energy by the wires.

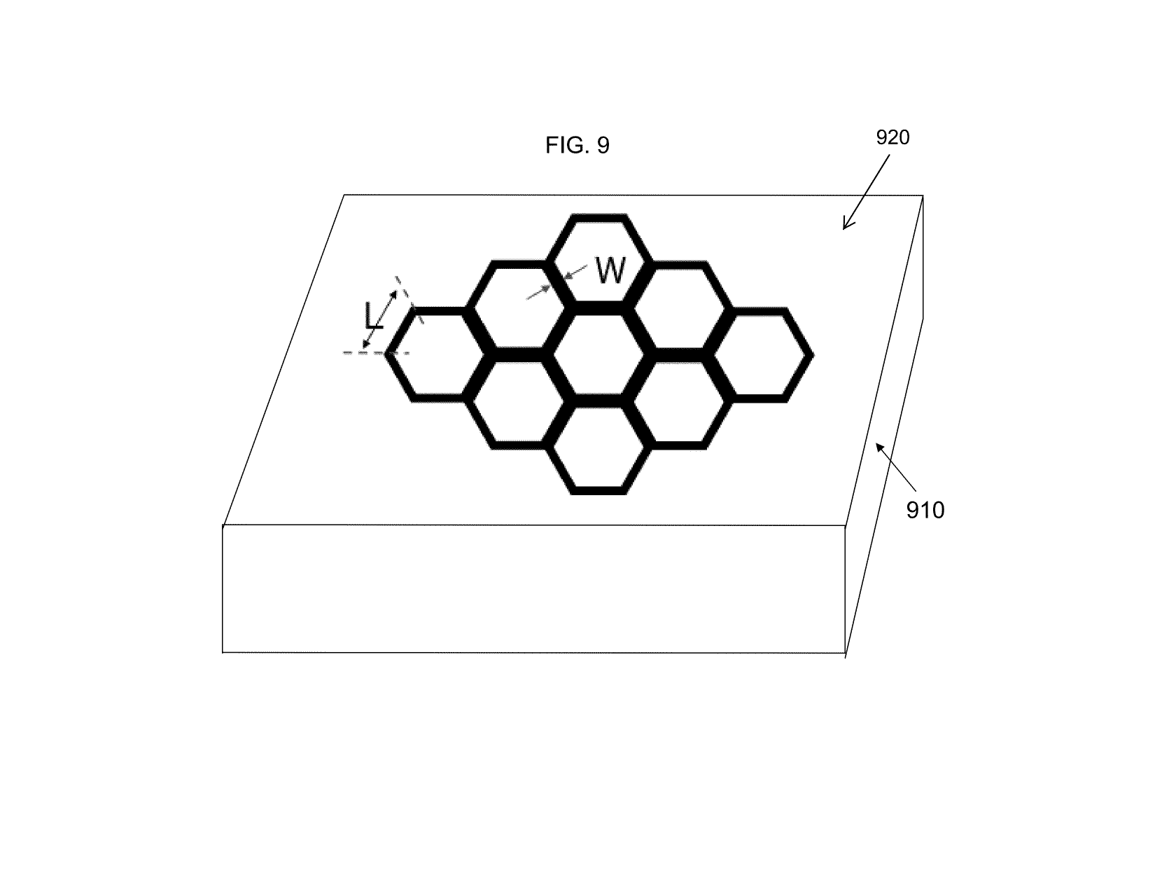

FIG. 9 is a perspective schematic diagram of a wire mesh structure such as that of any of FIG. 1, FIG. 2, FIG. 3 and FIG. 4 on a substrate 910, which substrate can be transparent to electromagnetic radiation having a wavelength of interest.

The substrate 910 of FIG. 9 can be made of any convenient material, or can be a device of interest upon which the wire mesh structure is produced. In instances where the substrate 910 is an active device, an intermediate layer 920 such as an oxide layer or a deposited film optionally can be provided to electrically insulate the active device from the wire mesh structure, as may be appropriate.

### APPLICATIONS AND BENEFITS OF THE INVENTION

An optically transmissive electrical conductor comprising a wire mesh with dimensions in the light scattering regime ˜0.5 microns <W<˜3 microns and ˜2.5 microns <L<˜15 microns as shown in FIG. 2. Electromagnetic transmission can be greater than that predicted by classical optics.

An optically transmissive electrical conductor comprising a wire mesh with dimensions in the light scattering regime ˜0.5 microns <W<˜3 microns and ˜2.5 microns <L<˜15 microns, and a field conductor as shown in FIG. 4. Electromagnetic transmission can be greater than that predicted by classical optics.

An optically transmissive electrical conductor comprising a wire mesh with dimensions in the plasmon interaction regime ˜20 nanometers <W<˜500 nanometers and ˜100 nanometers <L<˜1500 nanometers as shown in FIG. 3. Electromagnetic transmission can be greater than that predicted by classical optics and/or light scattering optics.

An optically transmissive electrical conductor comprising a wire mesh with dimensions in the plasmon interaction regime ˜20 nanometers <W<˜500 nanometers and ˜100 nanometers <L<˜1500 nanometers and a field conductor as shown in FIG. 4. Electromagnetic transmission can be greater than that predicted by classical optics and/or light scattering optics.

An optically transmissive electrical conductor comprising a wire mesh with dimensions in the plasmon interaction regime ˜20 nanometers <W<˜500 nanometers and ˜100 nanometers <L<˜1500 nanometers and a field conductor as shown in FIG. 4 where the geometries of the wires making up the wire mesh and the geometry of the wire mesh pattern, such as a close packed hexagonal array or square array or parallel wires or other configuration, is chosen to minimize the interaction of the wire mesh with certain frequencies of light incident on the structures.

An optically transmissive electrical conductor comprising a wire mesh with dimensions below a few wavelengths of electromagnetic radiation where the geometries of the wires making up the wire mesh patterns can be from but not limited to the following patterns: close packed hexagonal array, square array, parallel wires, wavy lines whose width and height dimensions are not constant along the wires.

Wire mesh structures made of metals such as gold, silver, aluminum, molybdenum, or other metals that produce or do not produce a plasmon interaction with incident radiation. The wire mesh structures can also be made of other electrical conducting materials such as PEDOT:PSS and other electrical conducting polymers or also semiconductors such as doped silicon, or conductive nanomaterials such as Ag nanowires, or carbon nanotubes.

The field conductors in which the wire mesh structures are embedded can be made of ITO (indium-tin-oxide), doped tin oxide, zinc oxide, PEDOT or other electrical conducting polymers, or other optically transmissive electrical conductors such as randomly arranged conductive nanomaterials such as Ag nanowires, or carbon nanotubes.

In some embodiments, the wire mesh structures are produced by a roll-to-roll nano-imprint-lithography process or a stamped nano-imprint-lithography process.

The invention can provide a polarizer for light or other electromagnetic radiation that minimizes light or electromagnetic absorption and thus maximizes the polarization efficiency of the device.

We now present an example of the use of such polarizers.

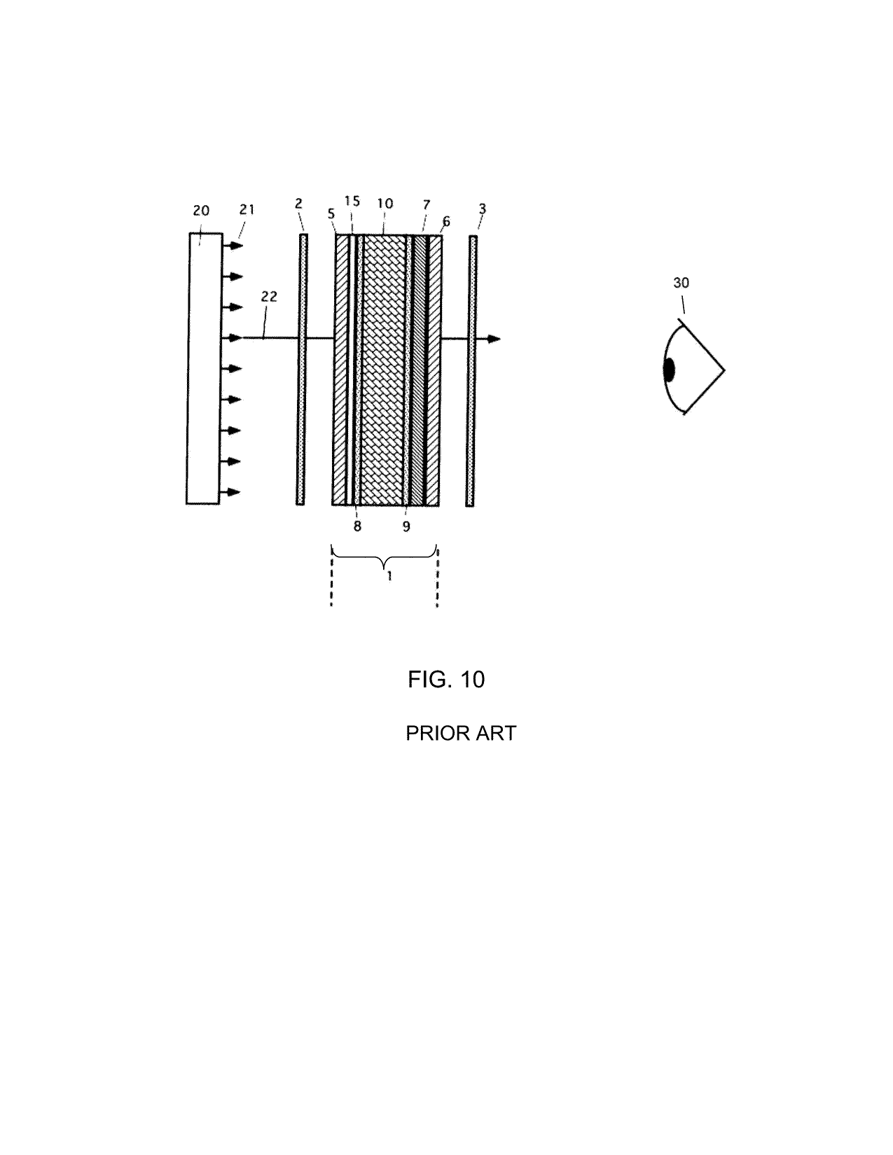

The conventional twisted nematic liquid crystal display (LCD) uses a liquid crystal placed between crossed linear polarizers to switch pixels from the on state to the off state. An example of a prior art LCD design is shown in FIG. 10, comprising a display assembly 1 placed between two crossed polarizers 2, 3. The display assembly comprises: two transparent plates 5, 6 which typically are made from glass; a circuit layer 7 used to switch the pixels in the display assembly; alignment layers 8, 9 used to align the nematic liquid crystal; and a volume of twisted nematic liquid crystal 10. A viewer 30 is illustrated as looking at polarizer 3.

As is well-known in the art, the nematic liquid crystal orients itself at the surface of the alignment layers, which in one common method are formed by brushing to achieve parallel microscratches on the layer's surface. The microscratches induce the alignment of the crystal. If the two alignment layers 8, 9 are orthogonal and the nematic liquid crystal aligns itself with each surface, a twist is required, and it is this twist that rotates the polarization of the light passing through the liquid crystal. The application of an electric field causes the nematic liquid crystal to align itself with the field, thus removing the twist and so removing the polarization rotation. The electric field is applied between the circuit 7 and an electrode layer 15 that in many cases comprises a thin coating of indium tin oxide (ITO) deposited directly on the glass plate 5.

A backlight 20 is used to provide rays 21, 22 that strike the back of polarizer 2. The electric fields of this light lie on two orthogonal axes that we term s and p. Backlight 20 may comprises one or more LEOs and a housing to diffuse light so that it is emitted uniformly toward the LCD. As is well known in the art, a conventional plastic linear polarizer absorbs light having electric field components orthogonal to the polarizer pass axis. In practical terms, referring to FIG. 10 this means that polarizer 2 will absorb 50% of the photons emitted by the backlight. Let us term the axis that polarizer 2 passes as the p-oriented polarization (e.g., 2(p)).

Light having polarization aligned with the pass axis of polarizer 2 (p) is passed through the liquid crystal display assembly 1. If the pixel is in the off state (meaning no applied electric field is present across the liquid crystal), the axis of polarization is rotated by the liquid crystal so that when the light 21 exits the display assembly, its polarization axis is rotated and it emerges with its electric field vector orthogonal to the p axis. In other words, it emerges with s polarization. If polarizer 3 is oriented at 90 degrees to polarizer 2, it will pass light with s-polarization and absorb light with p polarization. If polarizer 3 is oriented parallel to polarizer 2, it will pass p polarization and absorb s polarization. Whether or not light passes polarizer 3 depends on whether the liquid crystal has rotated the axis of polarization, which is controlled by whether or not an electric field is placed across the pixel. Polarizer 3 is often terms the “analyzer” and we shall use this term for polarizer 3.

A result of the use of absorbing polarizers is that the unused incident light is converted to heat. This has the disadvantage that the LCD temperature rises and may require cooling, particularly in projector applications.

It may be seen that the prior art displays using conventional polarization methods have the following disadvantages:

1. One half of the light emitted by the backlight system is absorbed in the first polarizer.

2. Of the remaining light, any light that is not passed to the viewer's 30 eyes is absorbed in the analyzer.

3. If the polarizers are fixed to the LCD, the temperature of the LCD will rise which interferes with LCD operation. If the polarizers are free-standing, they may need cooling particularly in projection applications.

Therefore, prior art LCDs do not efficiently use the light emitted by the backlight.

### A LIGHT RECYCLING BACKLIGHT

A backlight for an LCD that efficiently produces linearly polarized light would improve the overall optical efficiency of an LCD. Referring to FIG. 10, if the light 21 and 22 were all aligned in one linear polarization, then polarizer 1 would not be necessary and 50% of the light would not be absorbed in the LCD. Note that if an absorbing polarizer is merely affixed to the backlight, no improvement in optical efficiency is obtained, because 50% of the light emitted by the light source within the backlight is still absorbed by the polarizer.

Therefore it is an object of this invention to provide a backlight that does not absorb 50% of the radiation emitted by the lamp or LED within the backlight.

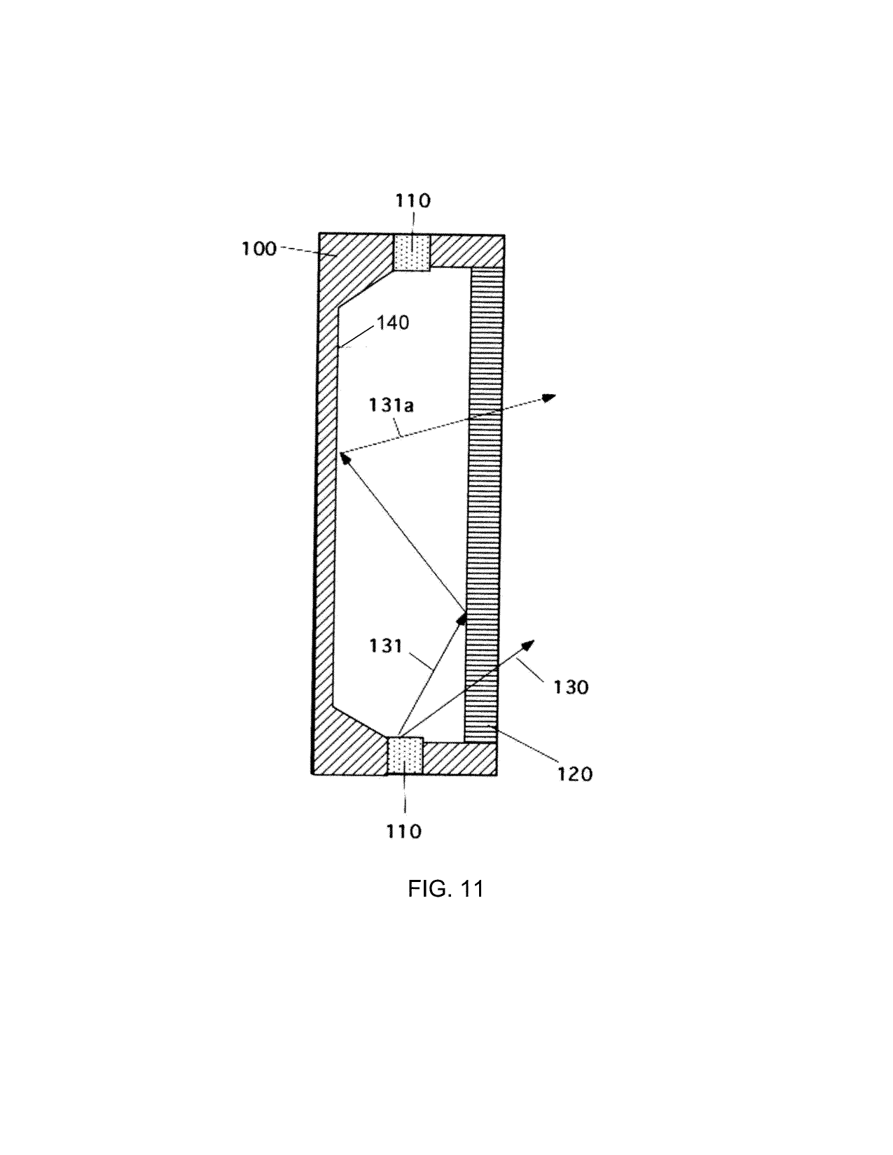

FIG. 11 illustrates a cross section of an embodiment of the invention, which is based on a wire grid polarizer (WGP) 120. Light is emitted by one or more sources 110 which may for example be LEDs. In other embodiments, sources 110 can be any convenient source of illumination or electromagnetic radiation having a desired wavelength or having an illumination component within a desired wavelength range. The light 130, 131 is emitted into a cavity within the backlight housing 100. The surfaces 140 of the cavity reflect light diffusely.

WGP 120 comprises a plurality of fine parallel wires having a pitch in the range of 50 to 300 nm and a width in the range of 25 to 150 nm. Accordingly, light with electric field parallel to the wires is reflected, and light with electric field orthogonal to the wires is passed. Thus the WGP is a linear polarizer similar to a plastic absorptive polarizer, except that rather than absorb one polarization, the WGP reflects one polarization and transmits the other polarization.

Referring again to FIG. 11, the light sources 110 emit light with random polarization (unpolarized light). Light ray 131 is representative of rays having the electric field aligned to the wires in the WGP 120. Therefore such rays are reflected by WGP 120. Ray 130 represents rays with electric field vector orthogonal to the wires in WGP 120. Such rays are transmitted by WGP 120.

Rays represented by ray 130 are reflected back into the backlight cavity and strike the diffuse surface 140. Diffuse reflection from such a surface randomizes the polarization. Ray 130a represents rays that are reflected with polarization orthogonal to the wires in WGP 120. Thus, such rays are transmitted. It can be seen that this design “recycles” photons so that (i) only linearly polarized photons are emitted by the wire grid polarizer, and (ii) rays emitted by the light sources 110 that are reflected internally until their polarization satisfies the exit criteria. This invention is therefore more efficient than a design based on absorptive polarizers. The advantage for portable devices such as tablets, cell phones and laptop computers is reduced power consumption.

This design may be further improved by adding brightness-enhancing films or other films designed to collimate the light radiated by the backlight.

### LIGHT-RECYCLING LCD

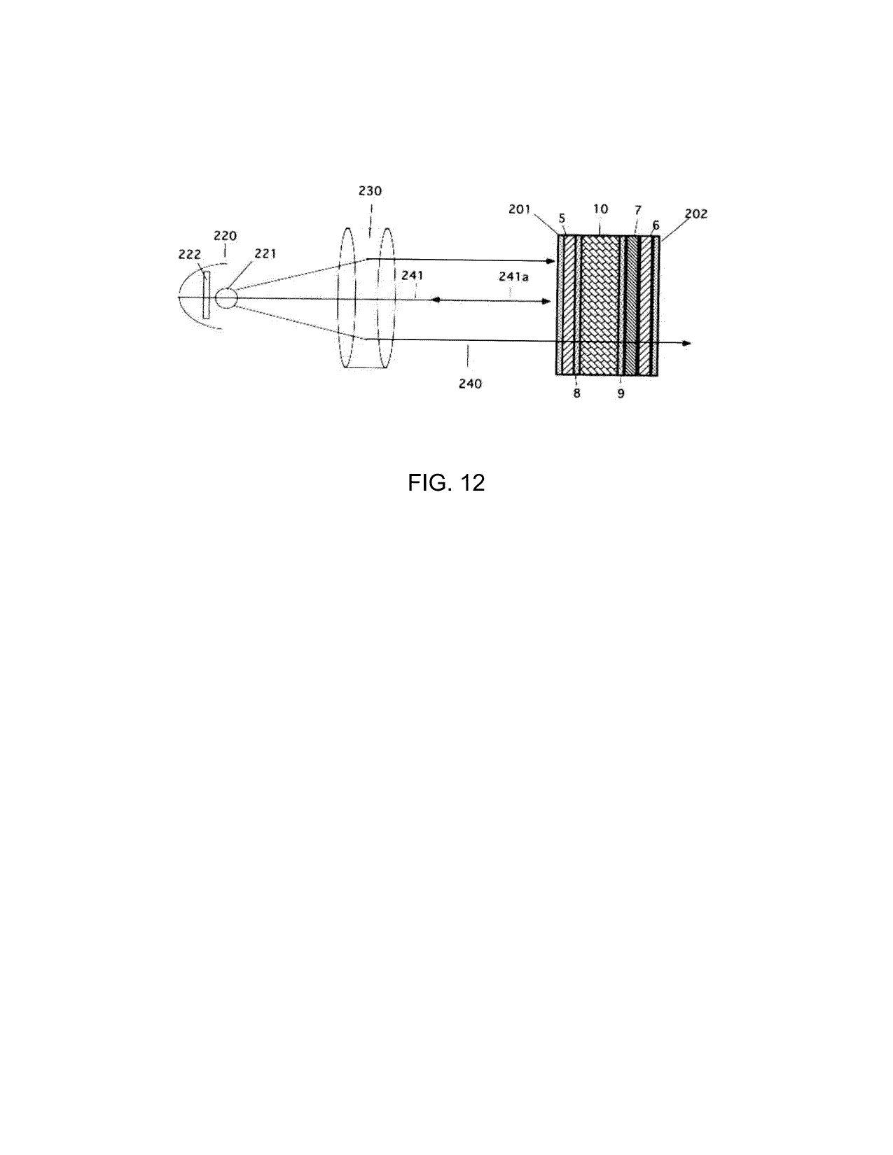

The invention described hereinabove may be applied directly to a liquid crystal display by replacing the absorptive polarizer with a WGP. In this way, unabsorbed light is returned to the illumination system. This invention is shown in FIG. 12 for the case of a projection system; however, it can be used with any backlight system. Since light is reflected rather than absorbed, this invention recycles light and reduces the temperature of the liquid crystal display.

Referring to FIG. 12, light is emitted by an illuminator comprising a lamp 221 and a reflector 220. The lamp 221 may for example be a xenon arc lamp. Light emitted by the lamp and collector passes through a condensing system 230 which collimates the light. The LCD comprises a modification of the conventional assembly in which the absorbing polarizer is replaced by WGP 201. Light ray 240 is representative of rays having polarization orthogonal to the wires in WGP 201. These rays are passed to the liquid crystal. Light ray 241 is representative of rays having polarization parallel to the wires in WGP 201. Such rays are reflected by WGP 201 and return to the illuminator (depicted as Ray 241a) and are reflected by collector 220 after passing twice through quarter wave plate 222. The quarter wave plate 222 rotates the polarization by 90° so that when ray 241a returns to the WGP 201, it is now oriented orthogonal to the wires and is passed to the liquid crystal. This invention accomplishes both an improvement in efficiency and a reduction in generation of heat at the polarizer.

The invention illustrated in FIG. 12 may be further improved by addition of a wire grid polarizer as analyzer 202. In this case, the analyzer returns light not used in forming the image to the illumination system and accomplishes (i) a further enhancement in efficiency and (ii) a further reduction in temperature of the LCD.

### LCD WITH INTERNAL WIRE-GRID POLARIZER

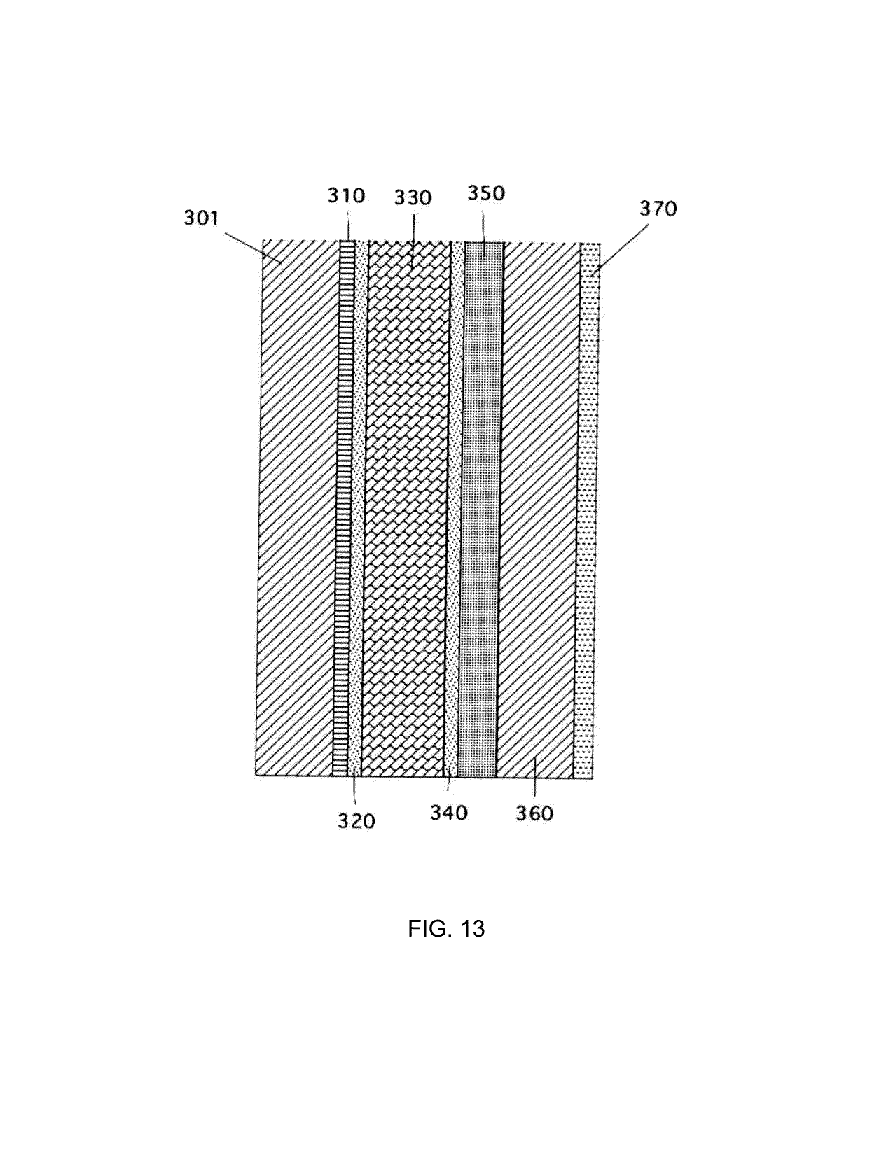

The prior art displays of the type shown in FIG. 10 use glass that has been coated with an optically transmissive electrical conductor such as indium tin oxide (ITO). The ITO is shown in FIG. 10 as an electrode 15. In another embodiment of this invention, the ITO is replaced by the wire grid polarizer, as shown in FIG. 13. In this embodiment, the glass plate 301 has been provided with a wire grid polarizer 310. The wires of the wire grid polarizer are connected in parallel at the boundaries of the display so that the wires are at a common potential and can act as an electrode.

Alternatively, the electrode may be made of a very thin layer of a transparent conductive material such as ITO, and the wire grid polarizer can be used to increase the conductivity of the electrode. In this way, the cost of the deposition of the optically transmissive electrical conductor may be reduced.

In this embodiment, the wire grid acts as both a polarizer and an electrode for the LCD. Referring again to FIG. 13, the wire grid polarizer 310 reflects light of one polarization, transmits the orthogonal polarization and creates a field across the alignment layers 320, 340, and the liquid crystal 330. The circuit 350 provides the other electrode. The second glass plate 360 may be provided with an analyzer 370. The analyzer 370 may also be a wire grid polarizer.

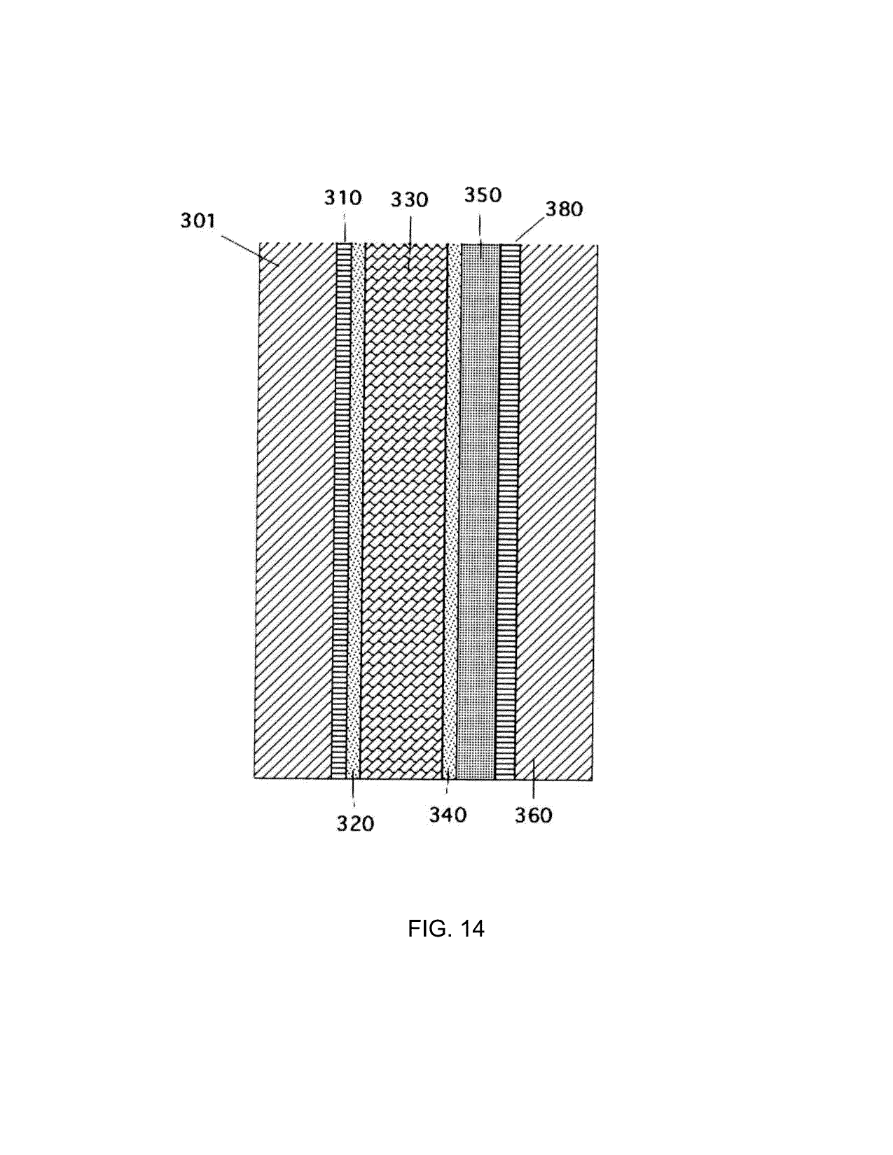

The analyzer may be placed within the LCD. FIG. 14 shows one method of placing a WGP 380 between the glass layer 360 and the circuit 350. Other locations are also possible. The advantage of placing the analyzer internal to the display is that it is then protected by the glass. FIG. 14 shows both WGP 310 and WGP 380 on the inside surfaces of the glass so that each is protected by the glass. Unlike absorptive plastic polarizers, integration of the WGP within the display is possible for three reasons: first, the WGP is thin (less than 1000 nm), second the WGP may be made with thin-film microelectronic deposition and patterning methods, and third as previously discussed the WGP does not absorb light, meaning that no heat is introduced within the LCD.

The integration of polarizers within the display therefore removes the cost element associated with placing plastic polarizers onto a display.

### REFERENCES

W. D. Slafer Roll-To-Roll Patterning of Transparent and Metallic Layers, Application number: 12/358,964, Publication number: US 2009/0130607 A1

M. G. Kang, and L. J. Guo, Nanoimprinted Semitransparent Metal Electrode and their Application in Organic Light-Emitting Diodes, Adv. Mater. 19, 1391-1396, 2007.

M. G. Kang and L. J. Guo, Semitransparent Cu Electrode On A Flexible Substrate and Its Application in Organic Light Emitting Diodes, J. Vac. Sci. & Technol. B. 25(6) (2007).

Xing Cheng, Dawen Li and L Jay Guo, A Hybrid Mask-Mould Lithography Scheme and its Application in Nanoscale Organic Thin Film Transistors, Nanotechnology, 17(4), 297, 2006.

Xing Cheng and L Jay Guo A Combined-Nanoimprint-And-Photolithography Patterning Technique, Journal Microelectronic Engineering, Volume 71, Issue 3-4, pg. 277-282, May 2004.

Xing Cheng and L Jay Guo, One-Step Lithography For Various Size Patterns With a Hybrid Mask-Mold, Journal Microelectronic Engineering, Volume 71 Issue 3-4, pg. 288-293, May 2004.

Wen-Chang Liao and Steve Lien-Chung Hsu, High Aspect Ratio Pattern Transfer in Imprint Lithography Using a Hybrid Mold, J. Vac. Sci. Technol. B 22, 2764 (2004).

Po-Ching Kao, Sheng-Yuan Chu, Chuan-Yi Zhan, Lien-Chung Hsu, Wen-Chang Liao, Fabrication of the Patterned Flexible OLEDs Using a Combined Roller Imprinting and Photolithography Method, 5th IEEE Conference on Nanotechnology, Volume 2, 693-695, 2005.

Hua Tan, Andrew Gilbertson, and Stephen Y. Chou, Roller Nanoimprint Lithography, J. Vac. Sci. Technol. B 16, 3926 (1998).

Carlos Pina-Hernandez, Jin-Sung Kim, Peng-Fei Fu, and L. Jay Guo, Nonresidual Layer Imprinting and New Replication Capabilities Demonstrated for Fast Thermal Curable Polydimethysiloxanes, J. Vac. Sci. Technol. B 25 (6), November/December 2007.

Helmut Schift, Christian Spreu, Arne Schleunitz, Jens Gobrecht, Anna Klukowska, Freimut Reuther, and Gabi Gruetzner, Easy Mask-Mold Fabrication for Combined Nanoimprint and Photolithography, J. Vac. Sci. Technol. B 27, 2850 (2009).

Helmut Schift, Christian Spreu, Menouer Saidani, Martin Bednarzik, Jens Gobrecht, Anna Klukowska, Freimut Reuther, Gabi Gruetzner, and Harun H. Solak, Transparent Hybrid Polymer Stamp Copies with Sub-50-Nm Resolution for Thermal and UV-Nanoimprint Lithography, J. Vac. Sci. Technol. B 28, C6M37 (2010).

Jurgen Hofinger, Wolfgang Pompe, Michael Mertig, Alexander Kirchner, Nina Schreiber, Anja Bluher, Steffen Roos, Daniela Keck, Beate Katzschner, Substrate with Spatially Selective Metal Coating, Method for Production and Use Thereof, US Patent Application Publication No. 2009/0124488 A1, 2009.

### THEORETICAL DISCUSSION

Although the theoretical description given herein is thought to be correct, the operation of the devices described and claimed herein does not depend upon the accuracy or validity of the theoretical description. That is, later theoretical developments that may explain the observed results on a basis different from the theory presented herein will not detract from the inventions described herein.

Any patent, patent application, patent application publication, journal article, book, published paper, or other publicly available material identified in the specification is hereby incorporated by reference herein in its entirety. Any material, or portion thereof, that is said to be incorporated by reference herein, but which conflicts with existing definitions, statements, or other disclosure material explicitly set forth herein is only incorporated to the extent that no conflict arises between that incorporated material and the present disclosure material. In the event of a conflict, the conflict is to be resolved in favor of the present disclosure as the preferred disclosure.

While the present invention has been particularly shown and described with reference to the preferred mode as illustrated in the drawing, it will be understood by one skilled in the art that various changes in detail may be affected therein without departing from the spirit and scope of the invention as defined by the claims.

What is claimed is:

1. An optically transmissive electrical conductor, comprising:
a substrate having at least one surface; and
an electrically conducting wire pattern disposed on said surface of said substrate, said electrically conducting wire pattern having wire dimensions smaller than a first wavelength of incident electromagnetic radiation, said optically transmissive electrical conductor configured to respond to said incident electromagnetic radiation having said first wavelength by transmitting said first wavelength through said conductor.

2. The optically transmissive electrical conductor of claim 1, wherein said electrically conducting wire pattern comprises a wire geometry selected to minimize a number of plasmon or polariton modes supported by said electrically conducting wire pattern.

3. The wire optically transmissive electrical conductor of claim 2, wherein said wire geometry is selected from a geometry consisting of a rectangle, a triangle, a circular geometry, and combinations thereof

4. The optically transmissive electrical conductor of claim 1, further comprising a continuous optically transmissive electrical conductor disposed adjacent said electrically conducting wire pattern.

5. The optically transmissive electrical conductor of claim 1, wherein said electrically conducting wire pattern comprises a metal selected from the group consisting of gold, silver, molybdenum, and aluminum.

6. The optically transmissive electrical conductor of claim 1, wherein said electrically conducting wire pattern comprises a semiconductor material selected from the group consisting of indium-tin-oxide and zinc oxide.

7. The optically transmissive electrical conductor of claim 1, further comprising an insulation layer situated between said surface of said substrate and said electrically conducting wire pattern.

8. The optically transmissive electrical conductor of claim 1, provided as a component in a device that is viewed by a viewer.

9. The optically transmissive electrical conductor of claim 1, in combination with at least one of:
a backlight; and
a liquid crystal display.

10. The optically transmissive electrical conductor of claim 9, wherein said optically transmissive electrical conductor and said backlight in combination are configured to produce a polarized light having an intensity greater than 50% of the intensity of the backlight without said optically transmissive electrical conductor.

11. The optically transmissive electrical conductor of claim 9, wherein said optically transmissive electrical conductor and said liquid crystal display in combination are configured to produce a display adapted to present information to a user.

12. The optically transmissive electrical conductor of claim 1, in combination with a separate light source situated on a first side of said optically transmissive electrical conductor, wherein the optically transmissive electrical conductor is configured as a first wire grid polarizer to transmit one polarization of said incident electromagnetic radiation emitted by said light source beyond said optically transmissive electrical conductor, and to reflect an orthogonal polarization of said incident electromagnetic radiation back toward said light source on said first side of said optically transmissive electrical conductor.

13. The optically transmissive electrical conductor of claim 12, further comprising a liquid crystal display situated on a second side of said optically transmissive electrical conductor, and further comprising a second wire grid polarizer configured as an analyzer, said second wire grid polarizer configured to reflect light orthogonal to its pass axis at a surface of said liquid crystal display distal to said first wire grid polarizer, so that such reflected light is propagated back through said liquid crystal display and toward said light source.

14. The optically transmissive electrical conductor of claim 12, further comprising:
a liquid crystal display situated on a second side of said optically transmissive electrical conductor;
a reflector; and
a quarter wave plate;
said light source, said reflector, said wave plate and said optically transmissive electrical conductor configured as said first wire grid polarizer are mutually arranged to transmit one polarization of said electromagnetic radiation emitted from said light source through said first wire grid polarizer to said liquid crystal display, and to reflect an orthogonal polarization of said electromagnetic radiation emitted from said light source from said first wire grid polarizer to said quarter wave plate, wherein said quarter wave plate is configured to rotate a plane of polarization of said orthogonal polarization so that upon reflection by said reflector, a resultant illumination is transmitted through said first wire grid polarizer.

15. A method of generating polarized light, comprising the steps of:
providing a source of unpolarized light having a wavelength λ, said source of unpolarized light producing light having an intensity I₀ per unit area;
causing said unpolarized light having said intensity I₀ per unit area to impinge on an electrically conducting wire pattern disposed on a surface of a material transparent at said wavelength λ;
causing light reflected backward from said electrically conducting wire pattern to impinge on a surface that randomizes by reflection a plane of polarization of said backwardly reflected light; and
causing said light having said randomized plane of polarization to again impinge on said electrically conducting wire pattern disposed on said surface of said material transparent at said wavelength λ;
whereby a fraction F of said unpolarized light having a wavelength λ, and an intensity I₀ per unit area is transmitted through said surface of said electromagnetically transparent material in a selected polarization, where F is more than 50%.

16. The method of claim 15, wherein said transmitted light is in a first polarization state and said reflected light is in a second polarization state orthogonal to said first polarization state.

17. The method of claim 16, wherein said transmitted light is used to operate a liquid crystal display.
